(19) United States
(12) Patent Application Publication
(10) Pub. No.: US 2017/0070365 A1
(43) Pub. Date: Mar. 9, 2017

(54) INTEGRATED MODULAR HOME GATEWAY MULTI-MEDIA ROUTER

(71) Applicant: VARUN VARMANI, New South Wales (AU)

(72) Inventor: VARUN VARMANI, New South Wales (AU)

(21) Appl. No.: 15/122,643

(22) PCT Filed: Mar. 4, 2015
(86) PCT No.: PCT/IB2015/051568

§ 371 Date: Aug. 31, 2016

(30) Foreign Application Priority Data
Mar. 4, 2014 (AU) 2014900706

(51) Int. Cl. H04L 12/66; H04L 12/24; H04L 29/08

(52) U.S. Cl. CPC H04L 12/66; H04L 67/1097; H04L 41/22; H04W 84/045

(57) ABSTRACT

The present invention relates to an improved multi-media router wherein a bundle of service modular devices are mounted together to deliver multiple network services which share a common base gateway Router. Apart from typical WAN and LAN connectivity, the base Router provides an improved power function which allows other modular devices to plug and play. Even though each modular device is an independent device for individual service(s), they interact in such a manner to the base gateway unit, in any order, so as to behave and operate as a singular device mode.

### FIELD OF THE INVENTION

This invention relates to a modular home gateway multimedia router. Particularly, the present invention relates to an improved router gateway device for sharing hardware and software resources and mounting multiple modular Service hardware devices, where each service module delivers distinct functional network service to the end user; wherein such selective service modules can be stacked one-on-top-of-the-other in any order to behave and operate in a singular device mode and as an integral part of the gateway device.

### BACKGROUND OF THE INVENTION

The functionality of the World Wide Web and other communication systems at home or workplace continues to grow. Modern electronic devices and gadgets provide several features and perform a number of tasks through Internet access. As a result, electronic devices which connect to the Internet, cable networks, satellite systems or communication networks are becoming increasingly popular. Home gateways allow individuals to connect to Internet service providers and with many connected devices within their home. Devices such as tablets, personal digital assistants, mobile and telephones, computers, printers, facsimiles, televisions, IoT appliances and other home networking devices can achieve both wired and wireless network connectivity within a home.

A Router provides an interface or a gateway between the customer premises (e.g., a Local Area Network (LAN)) and the Internet service provider network. Various network resources, such as switches and hubs, are used to manage traffic flow over LAN and Wide Area Networks (WAN). Router base carries WAN Ethernet port as well as offers LAN Ethernet interfaces. Typically, at home or in an office environment, a user or a plurality of users use either a wired residential or office Internet subscription (including a Wi-Fi connection plugged into a wired Router) or a wireless broadband card connection to access the Internet.

A number of electronic devices directly connect with a Router to provide different functions and this typically entails a number of physical ports/wires and power adaptors as such devices are plugged individually to the Router.

For example, to use audio speaker media so that any audio media accessible via a network can be played for best Audio performance, one requires a separate interface which entails a power cord/adaptor and other cables to connect with the audio speaker media as well as the Router. Such complicated process of connecting multiple devices is time consuming, energy consuming and relatively more expensive.

Therefore, there is a need for a router which behaves and operates in a singular device mode with plug and play modules to add the selective devices of customer choice and requirement at any time according to customer's need. Accordingly, the present invention has been made keeping in mind the above drawbacks in the prior art, and to develop a multi-media Router for home gateway module which has all the required processing capacity to provide scalability as the modules are added, even though each module will carry independent processing capacity, so that one module does not impact the efficiency of the other functioning module. Consequently, this invention leads to the whole home gateway system improving and providing convenience with cost effectiveness.

The above information disclosed in this background section is only for enhancement of understanding of the background of the invention and therefore it may contain information that does not form the prior art that is already known to a person of ordinary skill in the art.

### OBJECT OF THE INVENTION

The main object of this invention is to provide an improved router gateway device for sharing and mounting a bundle of multiple modular devices for selective functional modules wherein such selective functional modules can be stacked one-on-top-of-the other in any order to behave and operate in a singular device mode and as an integral part of the gateway device.

Yet another object of this invention is to provide an improved router with selectable network services such as Ethernet WAN, Ethernet LAN, Wi-Fi LAN, 3G/4G WAN, Power over Ethernet (PoE), Phone connectivity, media storage, M2M Controller, Media Player, and Touch Display and speaker module in singular device mode.

Yet another object of this invention is to provide an integrated modular home gateway multi-media router.

Yet another object of this invention is to provide a single device with various services through plug and play selectable functional services modules as per the customer's choice and requirement. This removes the complexity of configuring multiple devices with multiple configurations and makes it user friendly.

Yet another object of this invention is to obviate the requirements of number of physical ports/wires and power adaptors to operate multiple modular devices.

Yet another object of this invention is to minimize the cost spent on router accessories and the complexity of mounting, removing, and remounting different accessories to the router.

Yet another object of this invention is to provide an improved product that communicates between internal modular devices and is capable of communicating with external devices through standard APIs.

Yet another object of this invention is to enhance the service and hardware performance of multiple service modular devices by closely integrating service hardware within the residential gateway.

Yet another object of this invention is to provide a single operating system for all the functional modules and thereby making the entire operating system simpler and more cost effective.

Yet another object of this invention is to provide a single communication hub device for an entire home network and smart electronic devices or applications.

Yet another object of this invention is to provide a single power unit for an entire home network and smart electronic devices.

Still another object of this invention is to improve the integration of multiple modular devices with the home gateway unit.

### SUMMARY OF THE INVENTION

The present invention relates to an improved multi-media router wherein a bundle of service modular devices are mounted together to deliver multiple network services which share a common base gateway Router. Apart from typical WAN and LAN connectivity, the base Router provides an improved power function which allows other modular devices to plug and play. Even though each modular device is an independent device for individual service(s), they interact in such a manner to the base gateway unit, in any order, so as to behave and operate as a singular device mode.

In one embodiment of the present invention the Router as base unit has all the required processing capacity to provide scalability as the modules are added, even though each module will carry independent service level hardware processing capacity, so that one module does not impact the efficiency of the other functioning modules. The Power over Ethernet (PoE) is to be used with the Router base unit so that any external device can interface with the Residential Gateway via PoE. The Router also becomes the central device with Enterprise Bus Architecture configuration embedded in the Router so that any modular function connects and interacts with the Router base unit or another independent module through this Enterprise Bus Architecture. The circuit (pins) exposed to accept the connectivity with other modules will connect to a common bus interface, using common inbound APIs to connect and interwork with modules. Any one functional module is not directly connecting to any other functional module, thereby helping in reducing the complexity of the circuitry design and consequently reducing implementation cost. The Router base unit will also have a communication interface for a customer to be able to activate or configure the modules or services easily with a smart device with a customized Application or standard browser GUI. This communication interface can be a physical interface on the router base or an interface interacting with the Router base through the Enterprise Bus, wherein the physical interface is present on a separate module.

In another embodiment of the present invention there is a provision of a single device with plug and play various selective functional modules as per the customer's choice and requirement. The device will require only a single power source and single WAN connectivity. The present invention provides a single footprint eliminating the need of numerous power cords and network cables. The invention integrates individual and separate functional devices with plug and play mode (automation) to form a single integrated Product with flexibility of choice and ease of use.

### BRIEF DESCRIPTION OF THE DRAWINGS

Embodiments of the present invention are described herein with reference to the following drawing figures wherein:

FIG. 1 is a layout of traditional router connectivity on the left versus the new modular design on right in accordance with the present invention;

FIG. 2 is an overview of the Integrated Residential Gateway with modular functions in accordance with the present invention;

FIG. 3 is a conceptual diagram of a stackable design of the product in accordance with the present invention.

FIG. 4 is a plan view of stackable hardware design of the product in accordance with the present invention.

FIG. 5a is a top plan view of the router base with a physical connector/interface to connect to another service module with like connector in accordance with the present invention.

FIG. 5b is a front plan view of the router base in with physical interfaces accordance with the present invention.

FIG. 6a is a front plan view of a stacked module on the router base in accordance with the present invention.

FIG. 6b is a front plan view of two different modules stacked on the router base in accordance with the present invention.

FIG. 7a is front plan view of more than two different modules stacked on the router base and behaves like a singular device in accordance with the present invention.

FIG. 7b is a cross sectional view of more than two different modules stacked on the router base and behaves like a singular device in accordance with the present invention.

FIG. 8 is a plan cross-sectional view of connector design for optional module in accordance with the present invention.

### DETAILED DESCRIPTION OF THE EMBODIMENTS

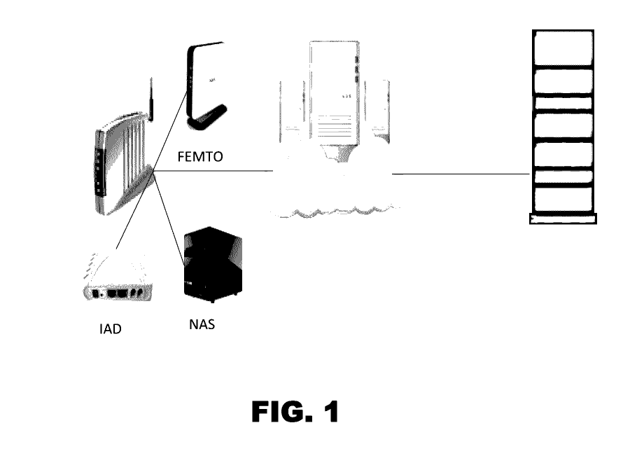

FIG. 1 is a layout of traditional router connectivity versus the new modular design in accordance with the present invention. Typically, multiple modular devices at home gateway are connected with a router with multitude of power cords and other physical connectivity means. However, the present device shows that modules when bundled together become a feature rich single device to fulfill the various purposes of WAN, LAN, Wi-Fi, 3G/4G, PoE, Phone connectivity, media storage, M2M Controller, Media Player, and Touch Display module.

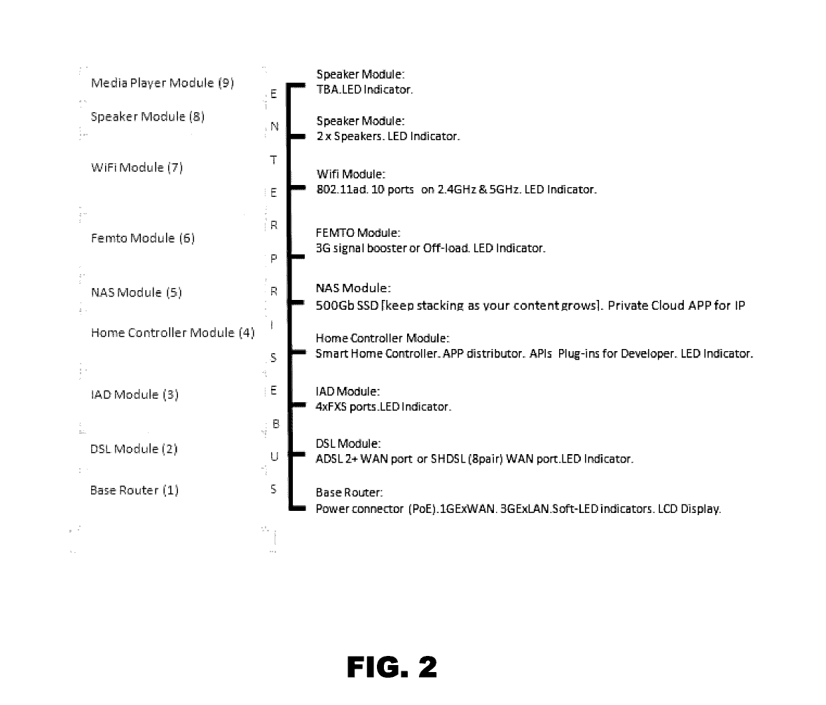

FIG. 2 depicts an overview of Modular functional Residential Gateway in accordance with the present invention. The functional aspect of the present invention will look and work like a singular operational device, however each functional Module is an independent function added as required by the user. This concept of making and adding functions on a modular basis, wherein such functional modules will fit on the device, allows a consumer to buy desired functions as per their requirements. The design allows reducing cost for consumers and providing performance required for the right functions. FIG. 2 describes that modules when bundled together become a feature rich single device. As per the present invention, the multiple modular devices which connect to the router base, include but are not limited to, in no specific order, the following:

1. ADSL2+ WAN connectivity module
2. SHDSL WAN connectivity module
3. FXS port Module with IAD function for VoIP connectivity

### 4. Home Controller Module for Home Automation/Security

5. NAS Module with SSD storage media which can be added multiple times in scalable configuration or RAID or backup configuration.
6. Femto Module to provide 3G or 4G or as available Mobile wireless connectivity for Mobile devices
7. WiFi Module with 802.11 ac or ad technology or standard version as and when available for devices with WiFi connectivity to connect to the Residential Gateway
8. Media Player Module for Gaming and Entertainment media
9. Speakers Module to have audio speaker media so that any audio media accessible via the Residential Gateway Modules can be played on the stack for best Audio performance

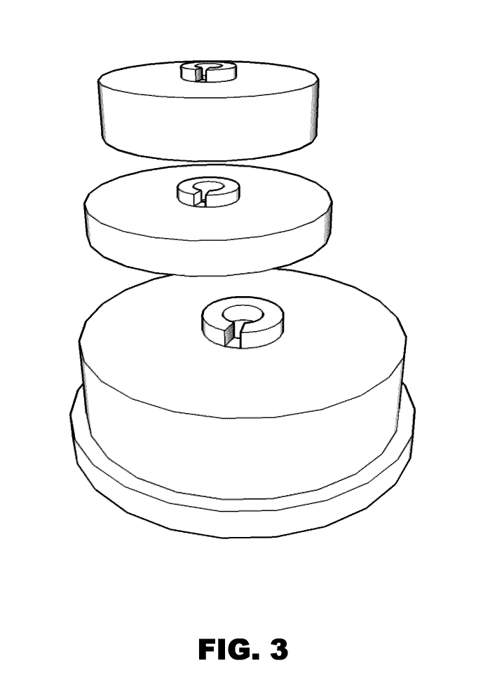

As shown, FIG. 3 is a schematic diagram of a stackable design of the product in accordance with the present invention. The present design of the invention is a novel stacking system that enhances the stacking performance over the conventional industrial chassis design with slots to add functional cards. This will appeal consumer as the ergonomics idea is to have this product look similar to that of a single device.

The performance aspect of the design is to have functions connected close to the base through a circuit so that there is no performance loss due to external wires or wireless connectivity between functional modules. The devices with separate functions in a typical traditional mode when connected externally communicate either wirelessly or with wires. However, the present invention aims at including this communication inside the product in modular stacking fashion, so as to improve the performance. It further aims to obviate the requirement of 802.11η or 802.11ac or 1 Gbps speeds on the LAN side. This resolves issues witnessed by home smart electronic devices communicating between each other, like requirements to buffer or re-transmit as there is lot of packet loss or congestion on LAN.

Further aspects of the invention provide a consolidation of various modules to a single router, resulting in more efficient and integrated single unit. Certain aspects of the present invention provide more efficient use as provided below:

Single Power Unit: The present design of the invention is to eliminate a large number of wires and power adaptors when connecting home smart electronic devices to a residential Gateway. The design allows base of the tower which is a Router module to have the power for the complete device that is when the new modules are added on the base, those new modules will be powered up via the base router module. This will eliminate the need for separate power wiring and data cables.

Power Supply: The present invention provides with power supply module having at least two types:

a. Low Power
b. High Power

Low Power: Low Power supplies required electricity power supply to a limited number of Modules (upto 6 Modules) comprising of selected Services hardware modules which will attain adequate supply by the Low Power Module.

High Power: High Power supply will be optional upgrade where customer has multiple Services which require higher power supply to perform. Also this upgradable supply will allow to deploy more than 6 service modules on to the Base Router.

Adequate power feed to all the electronics through single Power Module makes the product look and work in integrated manner. The Power feed is distributed alongside the communication interface to all the Service Module electronics and may use Power over Ethernet depending upon the power required by the Service.

Enterprise Bus: The present design of the invention is to provide simple connectivity between modules. Customer can buy and add/stack modules as per their need, which means no pre-set order is required for user to stack another module. To achieve this, an Enterprise Bus design is added to the base Router gateway; this will allow exposing of the physical connectors in order to connect any two modules together with the Bus and avoid a direct connection of any two modules with each other. This allows any modules in no pre-set order to connect to any module as essentially the modules are connecting to an Enterprise Bus.

Stacking Performance: The present design of the invention is a novel stacking system that enhances the stacking performance over a conventional industrial chassis design with slots to add functional cards. This will appeal consumer as the ergonomics idea is to have this product look similar to that of a single device. The performance aspect of the design is to have functions connected close to the base through a circuit so that there is no performance loss due to external wires or wireless connectivity between functional modules. The devices with separate functions in a typical traditional mode when connected externally communicate either wirelessly or with wires. However, the present invention aims at including this communication inside the product in modular stacking fashion, so as to improve the performance. It further aims to obviate the requirement of 802.11ac or 1 Gbps speeds on the LAN side. This resolves issues witnessed by home smart electronic devices communicating between each other, like requirements to buffer or re-transmit as there is lot of packet loss or congestion on LAN.

Power over Ethernet (PoE): Using PoE splitter in the design allows network extension and connectivity to smart electronic devices or gateways which require Ethernet wire connectivity to communicate in order to become a part of the home network. This addition in design allows FTTH Residential Gateways to communicate with the Base Router, where it is difficult and also expensive to connect to a Router device through cables.

Speakers on the Router: Having speakers or media platforms as modules and adding to the Router base allows users to play audio content being served through a Router (web) or on the Device. This allows providing best audio performance as consumers can store the content on the Device over NAS Module and play on the Device itself or play from the internet.

Designer Module: The aim of this module is to act as a bridge between modules but mainly to provide the ergonomic look to the Unit such that customers may want the unit to be presentable and meaningful cosmetically. Examples include but are not limited to a Digital timepiece with LCD display on the Module to provide the exterior mask.

Future Proofing Functions: New technology will keep coming and users will want to add these technologies to the LAN eco-system. The aim is to develop the modular functions such that users can keep getting better performance from the technologies customers prefer by adding it as a module on the base Router. Users can still connect to external devices with wire or wireless mode.

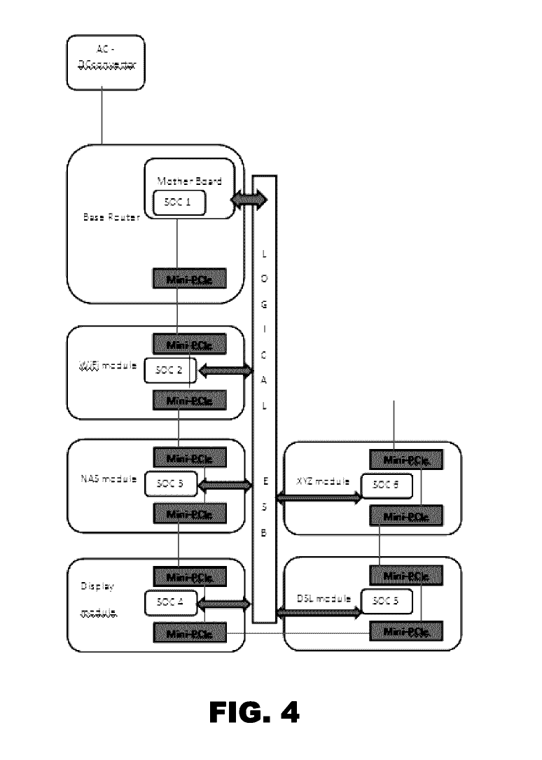

As shown in FIG. 4, a plan view of stackable hardware design of the product in accordance with the present invention is illustrated. The mother board of base router provided with system-on-a-chip (SoC) which is capable of communicating with other modules and act as Central Control Plane. Similarly, each module is provided with separate chipset and processing power but controlled by the base.

Physical interface can be PCIe to connect next physical module having equivalent mating interface to stack in. Second module onwards, the interface as shown is north and south, allowing next module to be able to stack on to it and distributing power, signalling, data etc feeds via the PCIe (or a proprietary BUS). Software ESB (logical bus) allows BASE module to control, provision or manage the other modules.

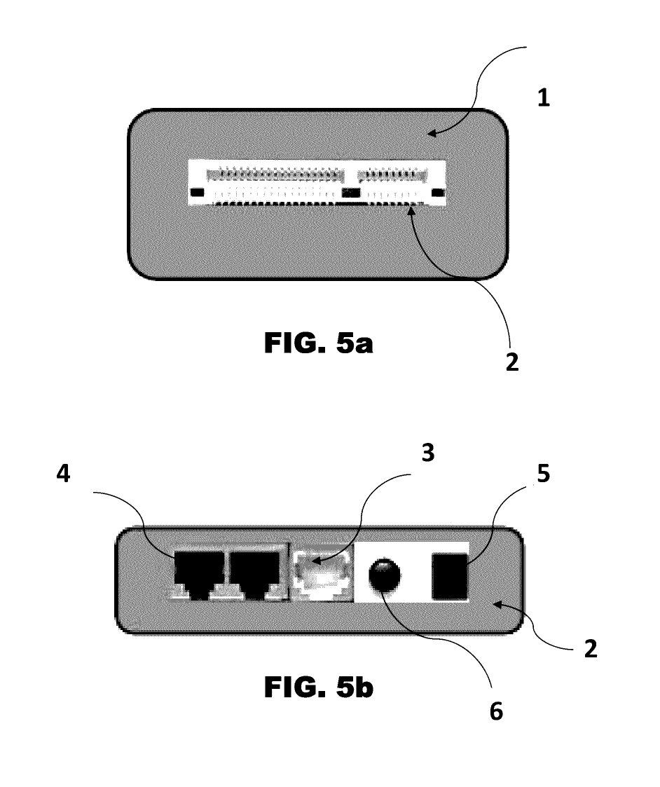

As shown in FIG. 5a, a top plan view of the router base in accordance with the present invention is illustrated. The router base 1 comprises with a customised connector 2 at top position allowing next module to be able to stack on to it in any order. The female and male connectors are customized in order to stackability of preferred module. The customised connector 2 is a common interface designed in order to have any Service Module connect in any order.

FIG. 5b is a front plan view of the router base in accordance with the present invention. Base Router 1 is provided with at least one WAN interface 3, at least one LAN interface 4, a power input interface 5, and a power indicator interface 6. Any other access technology such as ADSL, SHDSL, DOCSIS, WiFi, 3G, 4G is optional and available through separate Service Module.

Router base 1 has storage capacity for all the Hardware drivers to communicate to all stacked module's hardware. Router base 1 is provided with storage capacity having API adapters to communicate and control Service level software working in sequence with each Service module to deliver the required output. The Interface in order to connect two service modules allows power, signalling and data flow electronic channel path for smooth communication between the optional Service module and Router base 1.

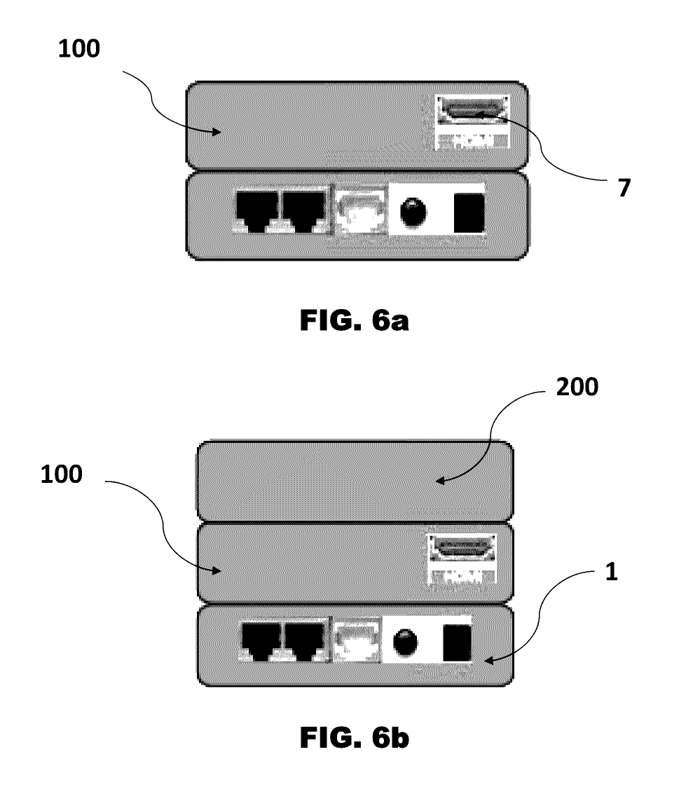

As shown in FIG. 6a, a front plan view of a stacked module on the router base in accordance with the present invention is illustrated. As shown in FIG. 6b, a front plan view of two different modules [100, 200] stacked on the router base in accordance with the present invention is illustrated. The modules can be stacked in any order/sequence in order to allow users to have flexibility to add the Network Services as they require.

Configuration of Integrated Service Gateway is completely managed through the Base router. Base Router has relevant interface configuration details and variables for each Service. When a new service is configured or multiple services are configured—all the relevant variables to connect and make the Service up and running are populated in the GUI interface based on browser GUI. This information is then tested and if Service is up user is notified via the GUI or if the Service is not up the error report is reported through the GUI.

When the new hardware is stacked or added to the Integrated Services Gateway, a unique identifier of the Service module is registered into the Base module and then relevant provisioning attributes already populated prior are then automatically injected into the Service module by the Base router. Each step of sequence is tested and Service is up, including allocation of adequate hardware resources to provide

Service performance required to deliver the service. Service module can also be manually provisioned using over-ride function, where user or operator can manually add the variable of the Service.

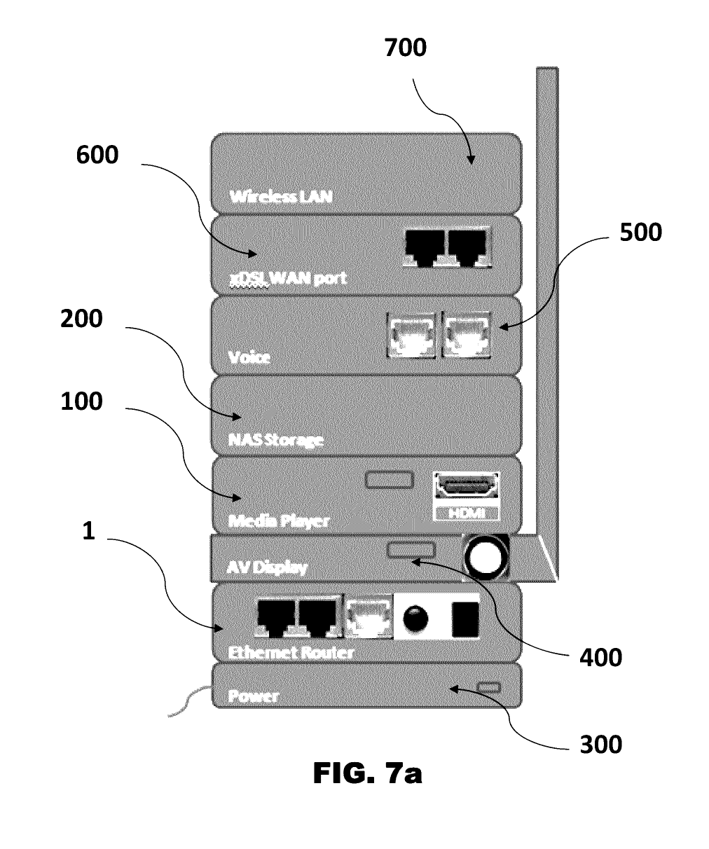

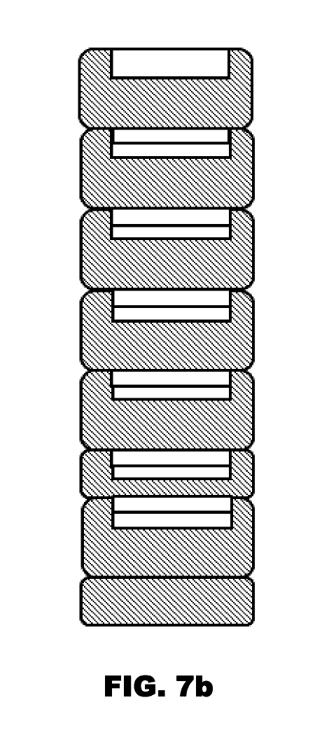

As shown in FIG. 7a, front plan view of more than two different modules [100, 200, 300, 400, 500, 600, 700] stacked on the router base and behaves like a singular device in accordance with the present invention is illustrated. The multiple modular devices [100, 200, 300, 400, 500, 600, 700] which connect to the router base, include but are not limited to, in no specific order, the following:

Services Modular gateway: Each discrete Network Service is modularised so that user can pick and choose which service is deployed on the Integrated Device.

Internet of Things Hub for Home: Device aims at simplifying the Service integration for user at home. With so many connected device where each different proprietary branded appliance is now getting IP connectivity and its dedicated APP, there is a need to simplify and have an available device which can embrace all the connected devices and allow user to control and report on each device from one single Unit. This device communicates via standard APIs AV Display unit to allow user to control IoT devices using touch screen, speech recognition, widgets through standard communication APIs. AV unit also allows user to play Audio and video files on NAS integrated module, cloud or web.

Expandability: If one NAS is not enough, add another or more to expand the storage capacity. If single Voice module is not enough and user require more ports, another voice module can be added to expand the ports capacity.
Share Services: IoT require different network services; this device provides key network services like storage, internet connectivity, voice connectivity, API bus from the Hub—instead of connecting phone line or providing storage space separately.

As shown in FIG. 7b, a cross sectional view of more than two different modules [100, 200, 300, 400, 500, 600, 700] stacked on the router base and behaves like a singular device in accordance with the present invention is illustrated.

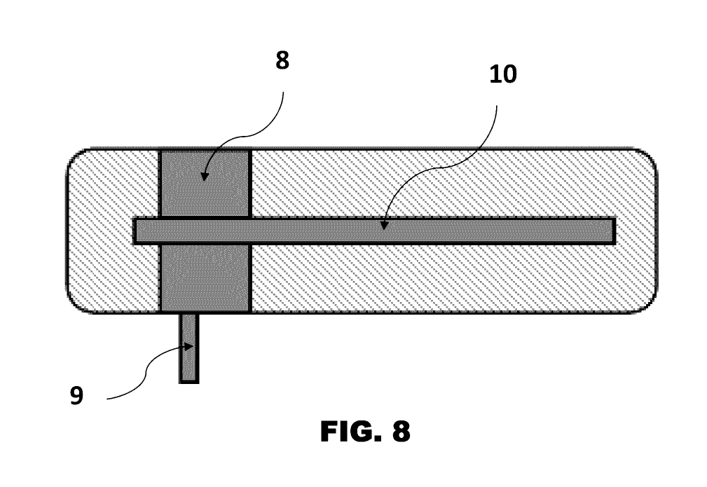

As shown in FIG. 8, a plan view of connector design for optional module in accordance with the present invention is illustrated. Physical interface of connector 2 comprises of a female connector 8; North side ready for next module to stack, a male connector 9; South side towards BASE router, and a functional card 10. The functional card 10 could be OTS mPCIe board which then has to connect to adaptor to join the North and South Connector. Where the function is not OTS then the board will directly connect to North and South connectors i.e. without adaptation.

Any and all communication is carried between Base Router modules with each or any service module. Two Service modules independent of Router Base will not directly communicate with each other unless directed and instructed by the Base Router. Base Router allocates the right interface resources including power, data speed, and communication signaling channels for each Service Module after identifying the Service Module through a unique identifier for the Service Module Hardware which gets registered with the Base Router as the Service Module is powered and connected to the integrated Services Gateway. Interfaces connecting two Service modules will become part of the hardware BUS architecture, so that Base Router is able to communicate to any Service Module as well as each Service Module is able to directly communicate with other module once instructed by Router Base.

The previous description of the disclosed embodiments is provided to enable any person skilled in the art to make or use the present invention. Various modifications to these embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the principles and novel features disclosed herein.

I claim:

1. An Integrated multimedia modular gateway comprising:
a gateway router base with shared hardware and software resources;
an Enterprise Bus Architecture configuration embedded in the router base;
sufficient interface resources integrated with the router base in order to allocate and distribute power, data speed, and communication signalling channels for one or more service modules stacked one-on-top-of-the-other in any order;
wherein:
the service modules are independent services enabled hardware with relevant software external to the router base and do not directly communicate with each other unless directed and instructed by the router base; and
the integrated multimedia stackable router operates in a singular device mode when number of hardware modules are stacked together and behave as an integral device with extended resources working in cohesion.

2. The Integrated multimedia modular gateway as claimed in claim 1, wherein the router base is provided with at least one WAN interface, at least one LAN interface with power insertion, a power input interface, a power indicator, hardware interface to connect physically to the service module, and all API adapters relevant for each service modules in order to be able to communicate with every other module stacked one on top of the other.

3. The Integrated multimedia modular gateway as claimed in claim 1, wherein the router base allocates the sufficient physical hardware and software resources including power, data speed, communication signaling channels for each service module after identifying the service module through a unique identifier for the service module hardware which gets registered with the base router as the service module is powered and connected to an integrated service gateway.

4. The Integrated multimedia modular gateway as claimed in claim 3, wherein the configuration of the integrated service gateway with all connected service modules is completely managed through the base router.

5. The Integrated multimedia modular gateway as claimed in claim 1, wherein the hardware bus interface and Enterprise Bus Architecture configuration is designed to connect at least two Service modules in such a manner that the router base is able to communicate to any service module and allow two service modules to directly communicate and share hardware or software resources with other.

6. The Integrated multimedia modular gateway as claimed in claim 1, wherein the hardware bus interface and Enterprise Bus Architecture configuration is a common interface designed to connect any service module in any order.

7. The Integrated multimedia modular gateway as claimed in claim 6, wherein the common interface is able to access technology and Services such as ADSL, SHDSL, DOCSIS, WiFi, 3G, 4G, NAS storage, IAD, Femto, Media Player, Speaker, Display unit through separate service module.

8. The Integrated multimedia modular gateway as claimed in claim 6, wherein the common interface in order to connect at least two service modules allocates enough power, signal, hardware resources and bandwidth for data flow via electronic channel for smooth communication and performance between the optional Service module and base router.

9. The Integrated multimedia modular gateway as claimed in claim 1, wherein the router base has storage capacity for all the associated hardware drivers and API adapters designed to communicate with each/other service module hardware.

10. A method for configuring the Integrated multimedia modular gateway as claimed in claim 1, the method steps comprising:
a) Configuring the service module required to stack on the integrated service gateway through the browser GUI interface;
b) stacking or adding new service module to the integrated service gateway;
c) identifying unique service module registered into the base module;
d) provisioning relevant attributes already populated automatically into the service module by the base router;
e) testing and servicing each provisioning step for integrating service module automatically to the device; and
f) allocating adequate hardware and software resources to service modules in order to provide Service performance required to deliver the service to end user.

11. The method for configuring the integrated multimedia modular gateways claimed in claim 10, wherein user or operator can manually add the variable of the service module by manually provisioned over-ride function.

12. The Integrated multimedia modular gateway as claimed in claim 5, wherein the service modules provide shared hardware and software resources for most service applications integrated or connected through LAN network; wherein:
a. NAS module provides shared disk storage to all the service modules and external application connected through the LAN network example is Media player module will use the NAS module to store the media and play content stored on NAS module; and
b. Voice module provides shared voice service for applications externally connected through the LAN network e.g. Security Camera can use the Voice service for back to base alarm without need for connecting a dedicated phone line.

13. The Integrated multimedia modular gateway as claimed in claim 1, wherein the multimedia modular gateway provides expansion in such a manner that one service module can be added to similar service module for capacity expansion.
